(19) United States
(12) Patent Application Publication
(10) Pub. No.: US 2011/0240223 A1
(43) Pub. Date: Oct. 6, 2011

(54) SUBSTRATE PROCESSING SYSTEM

(75) Inventors: Shinji Matsubayashi, Miyagi (JP); Satoru Kawakami, Miyagi (JP); Yasuhiro Tobe, Miyagi (JP); Masaru Nishimura, Miyagi (JP); Yasushi Yagi, Miyagi (JP); Teruyuki Hayashi, Miyagi (JP); Yuji Ono, Miyagi (JP); Fumio Shimo, Tokyo (JP)

(73) Assignee: TOKYO ELECTRON LIMITED, Minato-ku, Tokyo (JP)

(21) Appl. No.: 13/129,167

(22) PCT Filed: Nov. 11, 2009
(86) PCT No.: PCT/JP2009/069196

§ 371 Date: Jun. 14, 2011

(30) Foreign Application Priority Data
Nov. 14, 2008 (JP) 2008-292698

(51) Int. Cl. B08B 13/00; B05C 13/00

(52) U.S. Cl. 156/345.36; 118/500; 156/345.1; 156/345.35; 414/222.01

(57) ABSTRACT

There is provided a substrate processing system having high maintainability by widening a gap between various processing apparatuses connected with side surfaces of transfer modules and capable of achieving sufficient productivity by avoiding deterioration in throughput. The substrate processing system for manufacturing an organic EL device by forming a multiple number of layers including, e.g., an organic layer on a substrate includes at least one transfer module configured to be evacuable and arranged along a straight transfer route. Within the transfer module, a multiple number of loading/unloading areas for loading/unloading the substrate with respect to a processing apparatus and at least one stocking area positioned between the loading/unloading areas are alternately arranged along the transfer route in series, and the processing apparatus is connected with a side surface of the transfer module at a position facing each of the loading/unloading areas.

### TECHNICAL FIELD

The present invention relates to a substrate processing system for manufacturing, for example, an organic EL device.

### BACKGROUND ART

Recently, an organic EL device utilizing electroluminescence (EL) has been developed. Since the organic EL device generates almost no heat, it consumes lower power as compared to a cathode-ray tube or the like. Further, since the organic EL device is a self-luminescent device, there are some other advantages such as a view angle wider than that of a liquid crystal display (LCD), so that progress thereof in the future is expected.

Most typical structure of this organic EL device includes an anode (positive electrode) layer, a light emitting layer and a cathode (negative electrode) layer stacked sequentially on a glass substrate. In order to transmit light from the light emitting layer to the outside, a transparent electrode made of ITO (Indium Tin Oxide) is used as the anode layer on the glass substrate. Such organic EL device is generally manufactured by forming the light emitting layer and the cathode layer in sequence on the glass substrate having thereon the ITO layer (anode layer) and forming a sealing film layer on the cathode layer.

The organic EL device as described above is generally manufactured by a substrate processing system including various film forming apparatuses or etching apparatuses for forming a light emitting layer, a cathode layer, a sealing film layer, or the like.

Patent Document 1 describes a light emitting device (organic EL device) manufacturing apparatus for processing a substrate in a so-called face-up state. With the light emitting device manufacturing apparatus described in Patent Document 1, it is possible to manufacture a light emitting device (organic EL device) having a multiple number of layers including an organic layer with high productivity. Patent Document 1: Japanese Patent Laid-open Publication No. 2007-335203

### DISCLOSURE OF THE INVENTION

### Problems to Be Solved by the Invention

A processing system described in Patent Document 1 has a configuration in which a multiple number of processing apparatuses such as a film forming apparatus or an etching apparatus are connected with side surfaces of one or more transfer modules arranged along a transfer route. In this processing system, since moisture in the atmosphere is undesirable for an organic EL device, the organic EL device is generally manufactured by performing a process such as a film forming process, an etching process or a sealing process in a vacuum state.

However, in the processing system described in Patent Document 1, a gap between various processing apparatuses connected with the side surface of the transfer module is narrow, so that maintainability is not good. Particularly, in a five or more angled transfer module used in a conventional processing system, a gap between various processing apparatuses adjacent to each other is very narrow.

Therefore, the present invention provides a substrate processing system having high maintainability by widening a gap between various processing apparatuses connected with side surfaces of transfer modules and also provides a substrate processing system capable of achieving sufficient productivity by avoiding deterioration in throughput.

### Means for Solving the Problems

In accordance with an embodiment of the present invention, there is provided a substrate processing system for processing a substrate including at least one transfer module configured to be evacuable and arranged along a straight transfer route. Here, the transfer module may include a multiple number of loading/unloading areas, each of which is configured to load/unload the substrate with respect to a processing apparatus, and at least one stocking area positioned between the loading/unloading areas. Further, the processing apparatus may be connected with a side surface of the loading/unloading area.

In accordance with the substrate processing system, a multiple number of loading/unloading areas and the stocking area positioned between the loading/unloading areas may be formed within the transfer module. Further, the processing apparatus may be connected with a side surface of the transfer module at a position facing each of the loading/unloading areas. Accordingly, a gap corresponding to the stocking area positioned between the loading/unloading areas may be formed between the adjacent processing apparatuses on the lateral side of the transfer module.

In accordance with the substrate processing system, the transfer module may have a hexahedral structure of which a longitudinal direction is arranged along the transfer route. Further, in the transfer module, the multiple number of loading/unloading areas may be connected with the at least one stocking area via gate valves. Furthermore, a transfer arm may be installed in each of the loading/unloading areas and a transit table of the substrate is installed in the stocking area within the transfer module. Further, the at least one transfer module may be plural in number and an evacuable transit chamber may be installed between the transfer modules. Furthermore, a film forming process may be performed on an upper surface of the substrate in a face-up state.

Further, a mask aligner configured to place a mask having a predetermined pattern on the substrate may be connected with a side surface of the transfer module. In this case, the substrate processing system may further include a mask cleaning apparatus configured to clean a mask used for processing the substrate. Further, the mask cleaning apparatus may include a cleaning gas generation unit configured to activate a cleaning gas by plasma. Furthermore, the mask cleaning apparatus may include a processing chamber configured to accommodate the mask and a cleaning gas generation unit spaced apart from the processing chamber, and a cleaning gas activated by plasma in the cleaning gas generation unit may be introduced into the processing chamber by using a remote plasma method. In this case, the cleaning gas generation unit may be configured to activate the cleaning gas by using a downflow plasma method. Thus, the cleaning gas activated by using a downflow plasma method may be introduced into the processing chamber, so that activated radicals can be introduced into the processing chamber under an approximately normal temperature. Therefore, a mask can be cleaned without thermal damage. Further, the cleaning gas generation unit may be configured to generate high density plasma by using an inductively coupled plasma method. Furthermore, the cleaning gas generation unit may be configured to generate high density plasma with microwave power. Further, the cleaning gas may include any one of an oxygen radical, a fluorine radical, and a chlorine radical.

### Effect of the Invention

In accordance with the present invention, between processing apparatuses adjacent to each other at a side surface of a transfer module, a gap is formed at a position corresponding to a stocking area provided between loading/unloading areas. By using the gap formed between various processing apparatuses, it is possible to design a substrate processing system having high maintainability. Further, it is possible to obtain a substrate processing system capable of achieving sufficient productivity by avoiding deterioration in throughput.

### BRIEF DESCRIPTION OF THE DRAWINGS

FIGS. 1A to 1H are diagrams for explaining a manufacturing process of an organic EL device;

FIG. 2 is a diagram for explaining a substrate processing system in accordance with an embodiment of the present invention;

FIG. 3 is a schematic diagram for explaining a vapor deposition apparatus capable of forming a light emitting layer;

FIG. 4 is a schematic diagram for explaining a vapor deposition apparatus capable of forming a work function adjustment layer;

FIG. 5 is a schematic diagram for explaining a sputtering apparatus;

FIG. 6 is a schematic diagram for explaining an etching apparatus;

FIG. 7 is a schematic diagram for explaining a CVD apparatus;

FIG. 8 is a diagram for explaining a substrate processing system including a mask cleaning apparatus in accordance with an embodiment of the present invention;

FIG. 9 is a schematic diagram for explaining the mask cleaning apparatus;

FIG. 10 is a diagram for explaining an ICP type cleaning gas generation unit;

FIG. 11 is a diagram for explaining a cleaning gas generation unit capable of generating high density plasma by microwave power;

FIG. 12 is a diagram for explaining a substrate processing system including transfer routes formed in two rows in accordance with an embodiment of the present invention;

FIG. 13 is a diagram for explaining a substrate processing system in which a substrate can be transferred between transfer routes in accordance with an embodiment of the present invention;

FIGS. 14A to 14C provide diagrams for explaining a transfer module in which a transfer arm capable of moving along a transfer route is installed; and

FIG. 15 is a diagram for explaining a transfer module in which a gate valve is provided between each loading/unloading area and a stocking area.

### EXPLANATION OF CODES

A: Organic EL device

G: Substrate

L: Transfer route

M: Mask

1: Substrate processing system

10: Anode layer

11: Light emitting layer

12: Work function adjustment layer

13: Cathode layer

14: Protective layer

15: Conductive layer

16: Protective layer

20: Loader

21: First transfer module

22: Vapor deposition apparatus for light emitting layer

23: Second transfer module

24: First transit chamber

25: Third transfer module

26: Second transit chamber

27: Fourth transfer module

28: Unloader

40, 60 and 80: Front loading/unloading areas

41, 61 and 81: Rear loading/unloading areas

42, 62 and 82: Stocking areas

43, 44, 63, 64, 83 and 84: Transfer arms

45, 65 and 85: Transit tables

50: Vapor deposition apparatus for work function adjustment layer

51 and 90: Sputtering apparatuses

52 and 72: Mask stocking chambers

53, 73, 92 and 93: Mask aligners

70: Etching apparatus

71 and 91: CVD apparatuses

### BEST MODE FOR CARRYING OUT THE INVENTION

Hereinafter, embodiments of the present invention will be described in detail with reference to the accompanying drawings. To be specific, in the following embodiments, there will be explained a so-called face-up type substrate processing system 1 capable of manufacturing an organic EL device A by performing a process such as a film forming process onto an upper surface of a substrate G. In the specification and the drawings, elements having substantially the same function are assigned same reference numerals and redundant description thereof may be omitted.

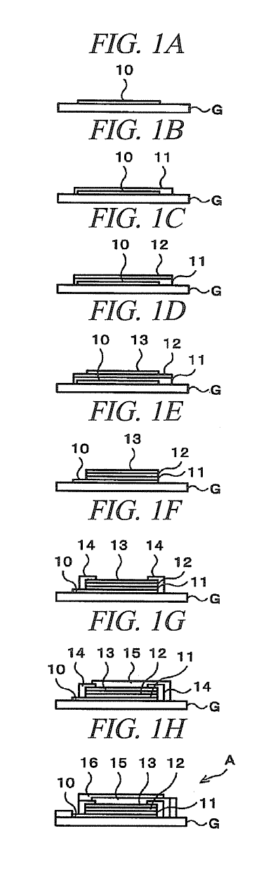

FIGS. 1A to 1H provide diagrams for explaining a manufacturing process of the organic EL device A in the substrate processing system 1 in accordance with an embodiment of the present invention. As depicted in FIG. 1A, the substrate G on which an anode (positive electrode) layer is formed is prepared. The substrate G is made of a transparent material such as glass. An anode layer 10 is made of a transparent conductive material such as ITO (Indium Tin Oxide). By way of example, the anode layer 10 is formed on the substrate G by a sputtering method.

As depicted in FIG. 1B, a light emitting layer (organic layer) 11 is formed on the anode layer 10 by a vapor deposition method. Further, the light emitting layer 11 has a multilayered structure in which, for example, a hole transport layer, a non-light-emitting layer (electron blocking layer), a blue light emitting layer, a red light emitting layer, a green light emitting layer, and an electron transport layer are layered.

Then, as depicted in FIG. 1C, a work function adjustment layer 12 made of Li or the like is formed on the light emitting layer 11 by a vapor deposition method.

Thereafter, as depicted in FIG. 1D, a cathode (negative electrode) layer 13 made of, for example, Ag, Al or the like is formed on the work function adjustment layer 12 and patterned in a predetermined shape by, for example, a sputtering method using a mask.

Subsequently, as depicted in FIG. 1E, by way of example, a plasma etching process is performed onto the light emitting layer 11 and the work function adjustment layer 12 while using the cathode layer 13 as a mask, and, thus, the light emitting layer 11 and the work function adjustment layer 12 are patterned.

Then, as depicted in FIG. 1F, an insulating protective layer 14 made of, for example, silicon nitride (SiN) is formed so as to cover edge of the light emitting layer 11, the work function adjustment layer 12, and the cathode layer 13 and a part of the anode layer 10. This protective layer 14 is formed by, for example, a CVD method using a mask.

Thereafter, as depicted in FIG. 1G, a conductive layer 15 made of, for example, Ag, Al or the like is formed in a predetermined pattern and electrically connected with the cathode layer 13. This conductive layer 15 is formed by, for example, a sputtering method using a mask.

Subsequently, as depicted in FIG. 1H, an insulating protective layer 16 made of, for example, silicon nitride (SiN) is formed in a predetermined pattern so as to cover a part of the conductive layer 15. This protective layer 16 is formed by, for example, a CVD method using a mask.

In the organic EL device A manufactured as described above, the light emitting layer 11 may emit light by applying voltage between the anode layer 10 and the cathode layer 13. This organic EL device A may be used for a display device or a surface emitting device (an illumination, a light source or the like) and can be used for various other electronic devices.

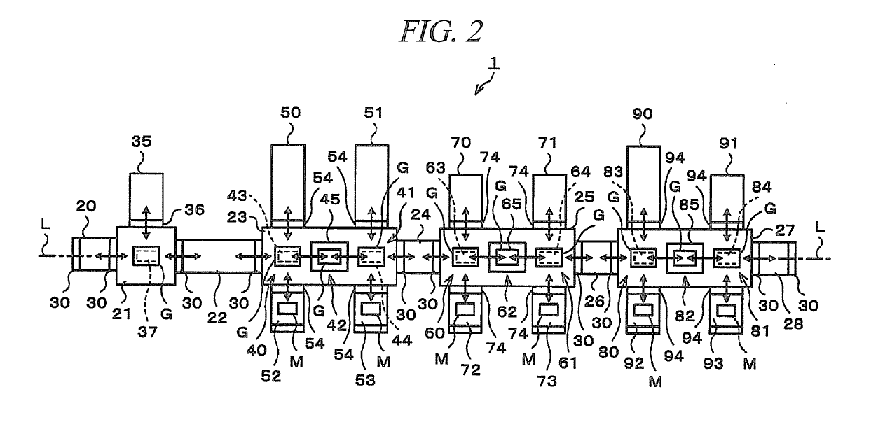

FIG. 2 is a diagram for explaining the substrate processing system 1 for manufacturing the organic EL device A in accordance with an embodiment of the present invention. In the substrate processing system 1, a straight transfer route L is formed by arranging, in sequence, a loader 20, a first transfer module 21, a vapor deposition apparatus 22 for the light emitting layer 11, a second transfer module 23, a first transit chamber 24, a third transfer module 25, a second transit chamber 26, a fourth transfer module 27, and an unloader 28 in series toward a transfer direction of the substrate G (in the right direction of FIG. 2).

Each gate valve 30 is provided in front of the loader (in the left of FIG. 2); between the loader 20 and the first transfer module 21; between the first transfer module 21 and the vapor deposition apparatus 22; between the vapor deposition apparatus 22 and the second transfer module 23; between the second transfer module 23 and the first transit chamber 24; between the first transit chamber 24 and the third transfer module 25; between the third transfer module 25 and the second transit chamber 26; between the second transit chamber 26 and the fourth transfer module 27; between the fourth transfer module 27 and the unloader 28; and in back of the unloader 28 (in the right of FIG. 2). Each inside of the loader 20, the first transfer module 21, the vapor deposition apparatus 22, the second transfer module 23, the first transit chamber 24, the third transfer module 25, the second transit chamber 26, the fourth transfer module 27, and the unloader 28 is sealed. Further, the insides of the loader 20, the first transfer module 21, the vapor deposition apparatus 22, the second transfer module 23, the first transit chamber 24, the third transfer module 25, the second transit chamber 26, the fourth transfer module 27, and the unloader 28 are evacuated by a non-illustrated vacuum pump.

A cleaning apparatus 35 of the substrate G is connected with a side surface of the first transfer module 21 via a gate valve 36. A transfer arm 37 is installed within the first transfer module 21. The substrate G loaded on the transfer arm 37 may be transferred from the loader 20 to the vapor deposition apparatus 22 along the transfer route L, and the substrate G may be transferred between the inside of the first transfer module 21 and the cleaning apparatus 35 in a direction orthogonal to the transfer route L.

Within the second transfer module 23, a front loading/unloading area 40, a rear loading/unloading area 41, and a single stocking area 42 between the front loading/unloading area 40 and the rear loading/unloading area 41 are formed. The second transfer module 23 has a hexahedral structure of which a longitudinal direction is arranged along the transfer route L. The front loading/unloading area 40, the stocking area 42, and the rear loading/unloading area 41 are arranged in sequence and in series toward a transfer direction (rightward direction of FIG. 2) of the substrate G along the transfer route L within the second transfer module 23.

Within the second transfer module 23, a transfer arm 43 is installed in the front loading/unloading area 40, a transfer arm 44 is installed in the rear loading/unloading area 41, and a transit table 45 is installed in the stocking area 42.

A vapor deposition apparatus 50 for the work function adjustment layer 12, a sputtering apparatus 51, a mask stocking chamber 52, and a mask aligner 53 are connected with side surfaces of the second transfer module 23 via each gate valve 54. The vapor deposition apparatus 50 and the mask stocking chamber 52 are provided at opposite side surfaces of the second transfer module 23. Further, the vapor deposition apparatus 50 and the mask stocking chamber 52 are positioned to face the front loading/unloading area 40. A mask M for forming a predetermined pattern is waiting in the mask stocking chamber 52.

Within the second transfer module 23, the transfer arm 43 installed in the front loading/unloading area 40 may transfer the substrate G from the vapor deposition apparatus 22 to the stocking area 42 along the transfer route L and may transfer the substrate G between the inside of the second transfer module 23 and the vapor deposition apparatus in the direction orthogonal to the transfer route L. Further, transfer arm 43 installed in the front loading/unloading area 40 may transfer the mask M between the mask stocking chamber 52 and the stocking area 42.

The sputtering apparatus 51 and the mask aligner 53 are provided at opposite side surfaces of the second transfer module 23. Further, the sputtering apparatus 51 and the mask aligner 53 are positioned to face the rear loading/unloading area 41.

Within the second transfer module 23, the transfer arm 44 installed in the rear loading/unloading area 41 may transfer the substrate G from the stocking area 42 to the first transit chamber 24 along the transfer route L and may transfer the substrate G between the inside of the second transfer module 23 and the sputtering apparatus 51 and between the inside of the second transfer module 23 and the mask aligner 53 in the direction orthogonal to the transfer route L. Further, transfer arm 44 installed in the rear loading/unloading area 41 may transfer the mask M between the stocking area 42 and the mask aligner 53.

Within the second transfer module 23, the substrate G and the mask M may be waiting on the transit table 45 installed in the stocking area 42. Further, any processing apparatus is not connected with a side surface of the second transfer module 23 at a position facing the stocking area 42. For this reason, a gap having substantially the same width as that of the transit table 45 is formed at a position facing the stocking area 42 between the vapor deposition apparatus 50 and the sputtering apparatus 51 or between the mask stocking chamber 52 and the mask aligner 53 in the side surface of the second transfer module 23.

Within the third transfer module 25, a front loading/unloading area 60, a rear loading/unloading area 61, and a single stocking area 62 between the front loading/unloading area 60 and the rear loading/unloading area 61 are formed. The third transfer module 25 has a hexahedral structure of which a longitudinal direction is arranged along the transfer route L. The front loading/unloading area 60, the stocking area 62, and the rear loading/unloading area 61 are arranged in sequence and in series toward the transfer direction (rightward direction of FIG. 2) of the substrate G along the transfer route L within the third transfer module 25.

Within the third transfer module 25, a transfer arm 63 is installed in the front loading/unloading area 60, a transfer arm 64 is installed in the rear loading/unloading area 61, and a transit table 65 is installed in the stocking area 62.

An etching apparatus 70, a CVD apparatus 71, a mask stocking chamber 72, and a mask aligner 73 are connected with side surfaces of the third transfer module 25 via each gate valve 74. The etching apparatus 70 and the mask stocking chamber 72 are provided at opposite side surfaces of the third transfer module 25. Further, the etching apparatus 70 and the mask stocking chamber 72 are positioned to face the front loading/unloading area 60. A mask M for forming a predetermined pattern is waiting in the mask stocking chamber 72.

Within the third transfer module 25, the transfer arm installed in the front loading/unloading area 60 may transfer the substrate G from the first transit chamber 24 to the stocking area 62 along the transfer route L and may transfer the substrate G between the inside of the third transfer module 25 and the etching apparatus 70 in the direction orthogonal to the transfer route L. Further, transfer arm 63 installed in the front loading/unloading area 60 may transfer the mask M between the mask stocking chamber 72 and the stocking area 62.

The CVD apparatus 71 and the mask aligner 73 are provided at opposite side surfaces of the third transfer module 25. Further, the CVD apparatus 71 and the mask aligner 73 are positioned to face the rear loading/unloading area 61.

Within the third transfer module 25, the transfer arm installed in the rear loading/unloading area 61 may transfer the substrate G from the stocking area 62 to the second transit chamber 26 along the transfer route L and may transfer the substrate G between the inside of the third transfer module 25 and the CVD apparatus 71 and between the inside of the third transfer module 25 and the mask aligner in the direction orthogonal to the transfer route L. Further, transfer arm 64 installed in the rear loading/unloading area 61 may transfer the mask M between the stocking area 62 and the mask aligner 73.

Within the third transfer module 25, the substrate G and the mask M may be waiting on the transit table 65 installed in the stocking area 62. Further, any processing apparatus is not connected with a side surface of the third transfer module 25 at a position facing the stocking area 62. For this reason, a gap having substantially the same width as that of the transit table 65 is formed at a position facing the stocking area 62 between the etching apparatus 70 and the CVD apparatus 71 or between the mask stocking chamber 72 and the mask aligner 73 in the side surface of the third transfer module 25.

Within the fourth transfer module 27, a front loading/unloading area 80, a rear loading/unloading area 81, and a single stocking area 82 between the front loading/unloading area 80 and the rear loading/unloading area 81 are formed. The fourth transfer module 27 has a hexahedral structure of which a longitudinal direction is arranged along the transfer route L. The front loading/unloading area 80, the stocking area 82, and the rear loading/unloading area 81 are arranged in sequence and in series toward the transfer direction (rightward direction of FIG. 2) of the substrate G along the transfer route L within the fourth transfer module 27.

Within the fourth transfer module 27, a transfer arm 83 is installed in the front loading/unloading area 80, a transfer arm 84 is installed in the rear loading/unloading area 81, and a transit table 85 is installed in the stocking area 82.

A sputtering apparatus 90, a CVD apparatus 91, a mask aligner 92, and a mask aligner 93 are connected with side surfaces of the fourth transfer module 27 via each gate valve 94. The sputtering apparatus 90 and the mask aligner are provided at opposite side surfaces of the fourth transfer module 27. Further, the sputtering apparatus 90 and the mask aligner 92 are positioned to face the front loading/unloading area 80.

Within the fourth transfer module 27, the transfer arm 83 installed in the front loading/unloading area 80 may transfer the substrate G from the second transit chamber 26 to the stocking area 82 along the transfer route L and may transfer the substrate G between the inside of the fourth transfer module 27 and the sputtering apparatus 90 and between the inside of the fourth transfer module 27 and the mask aligner 92 in the direction orthogonal to the transfer route L.

The CVD apparatus 91 and the mask aligner 93 are provided at opposite side surfaces of the fourth transfer module 27. Further, the CVD apparatus 91 and the mask aligner 93 are positioned to face the rear loading/unloading area 81.

Within the fourth transfer module 27, the transfer arm 84 installed in the rear loading/unloading area 81 may transfer the substrate G from the stocking area 82 to the unloader 28 along the transfer route L and may transfer the substrate G between the inside of the fourth transfer module 27 and the CVD apparatus 91 and between the inside of the fourth transfer module 27 and the mask aligner 93 in the direction orthogonal to the transfer route L.

Within the fourth transfer module 27, the substrate G may be waiting on the transit table 85 installed in the stocking area 82. Further, any processing apparatus is not connected with a side surface of the fourth transfer module 27 at a position facing the stocking area 82. For this reason, a gap having substantially the same width as that of the transit table 85 is formed at a position facing the stocking area 82 between the sputtering apparatus 90 and the CVD apparatus 91 or between the mask aligner 92 and the mask aligner 93 in the side surface of the fourth transfer module 27.

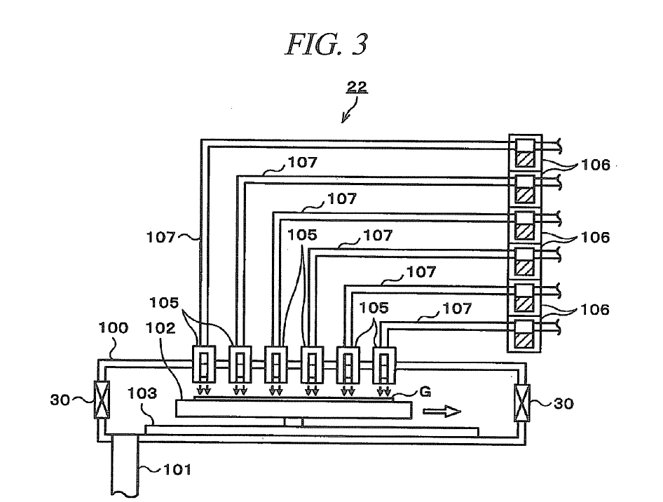

FIG. 3 is a schematic diagram for explaining the vapor deposition apparatus 22. The vapor deposition apparatus 22 depicted in FIG. 3 forms the light emitting layer 11 depicted in FIG. 1B by a vapor deposition method.

The vapor deposition apparatus 22 includes a sealed processing chamber 100. The processing chamber 100 has a hexahedral structure of which a longitudinal direction is arranged along the transfer route L and front and rear surfaces of the processing chamber 100 are connected with the first transfer module 21 and the second transfer module 23, respectively, via the gate valves 30.

A bottom surface of the processing chamber 100 is connected with an exhaust line 101 including a vacuum pump (not shown), so that the inside of the processing chamber 100 is depressurized. Within the processing chamber 100, a holding table 102 configured to horizontally hold thereon the substrate G is installed. The substrate G is mounted on the holding table 102 in a face-up state in which the substrate G's upper surface on which the anode layer 10 is formed faces upwards. The holding table 102 moves on a rail 103 installed along the transfer route L to transfer the substrate G along the transfer route L.

A multiple number of vapor deposition heads 105 are arranged on a ceiling of the processing chamber 100 along the transfer direction (the transfer route L) of the substrate G. Each of the vapor deposition heads 105 is connected with each of vapor supply sources 106 for supplying vapor of film forming materials for forming the light emitting layer 11 via each supply line 107. While the vapor of the film forming materials supplied from the vapor supply sources 106 is being discharged from each of the vapor deposition heads 105, the substrate G held on the holding table 102 is transferred along the transfer route L, and, thus, the light emitting layer 11 is formed on the upper surface of the substrate G by forming a hole transport layer, a non-light-emitting layer, a blue light emitting layer, a red light emitting layer, a green light emitting layer, and an electron transport layer in sequence on the upper surface of the substrate G.

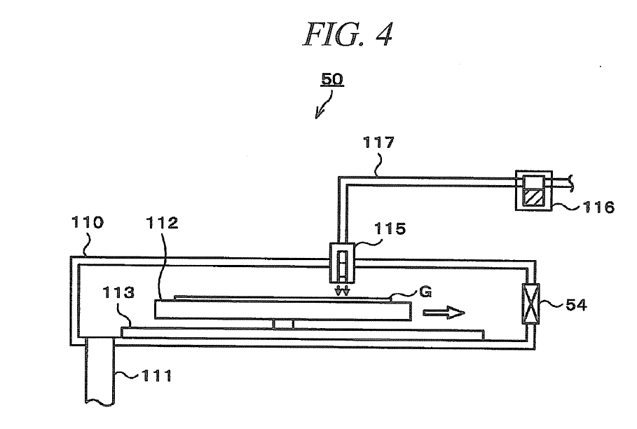

FIG. 4 is a schematic diagram for explaining the vapor deposition apparatus 50. The vapor deposition apparatus 50 depicted in FIG. 4 forms the work function adjustment layer 12 depicted in FIG. 1C by a vapor deposition method.

The vapor deposition apparatus 50 includes a sealed processing chamber 110. The processing chamber 110 has a hexahedral structure of which a longitudinal direction is arranged along a direction orthogonal to the transfer route L and a front surface of the processing chamber 110 is connected with a side surface of the second transfer module 23 via the gate valve 54.

A bottom surface of the processing chamber 110 is connected with an exhaust line ill including a vacuum pump (not shown), so that the inside of the processing chamber 110 is depressurized. Within the processing chamber 110, a holding table 112 configured to horizontally hold the substrate G is installed. The substrate G is mounted on the holding table 112 in a face-up state in which the substrate G's upper surface on which the light emitting layer 11 is formed faces upwards. The holding table 112 moves on a rail 113 installed along the direction orthogonal to the transfer route L to transfer the substrate G along the direction orthogonal to the transfer route L.

A vapor deposition head 115 is positioned on a ceiling of the processing chamber 110. The vapor deposition head 115 is connected with a vapor supply source 116 for supplying vapor of a film forming material such as Li for forming the work function adjustment layer 12 via a supply line 117. While the vapor of the film forming material supplied from the vapor supply source 116 is being discharged from the vapor deposition head 115, the substrate G held on the holding table 112 is transferred along the direction orthogonal to the transfer route L, and, thus, the work function adjustment layer 12 is formed on the upper surface of the substrate G.

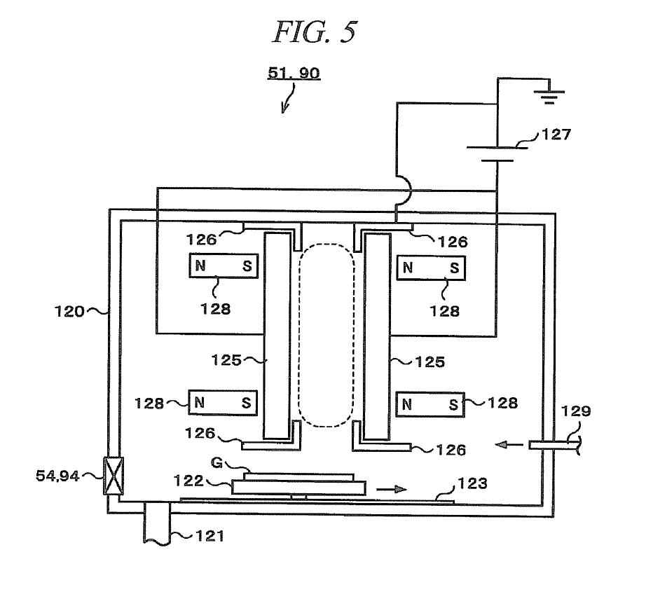

FIG. 5 is a schematic diagram for explaining the sputtering apparatuses 51 and 90. The sputtering apparatuses 51 and 90 have the same configuration. The sputtering apparatuses 51 and 90 depicted in FIG. 5 form the cathode (negative electrode) layer 13 depicted in FIG. 1D and the conductive layer 15 depicted in FIG. 1G by a sputtering method.

Each of the sputtering apparatuses 51 and 90 includes a sealed processing chamber 120. The processing chamber 120 has a hexahedral structure of which a longitudinal direction is arranged along the direction orthogonal to the transfer route L, and a front surface of the processing chamber 120 of the sputtering apparatus 51 is connected with a side surface of the second transfer module 23 via the gate valve 54 and a front surface of the processing chamber 120 of the sputtering apparatus 90 is connected with a side surface of the fourth transfer module 27 via the gate valve 94.

A bottom surface of the processing chamber 120 is connected with an exhaust line 121 including a vacuum pump (not shown), so that the inside of the processing chamber 120 is depressurized. Within the processing chamber 120, a holding table 122 configured to horizontally hold the substrate G is installed. The substrate G is mounted on the holding table 122 in a face-up state in which the substrate G's upper surface on which the light emitting layer 11 is formed faces upwards. The holding table 122 moves on a rail 123 installed along the direction orthogonal to the transfer route L to transfer the substrate G along the direction orthogonal to the transfer route L.

These sputtering apparatuses 51 and 90 are facing target sputtering (FTS) apparatuses in which a pair of flat plate targets 125 face each other with a predetermined gap therebetween. The targets 125 are made of, for example, Ag, Al or the like. Ground electrodes 126 are positioned at an upper side and a lower side of the targets 125, and a power supply 127 applies voltage between the targets 125 and the ground electrodes 126. Further, magnets 128 for generating a magnetic field between the targets 125 are positioned outside the targets 125. Furthermore, a gas supply unit 129 for supplying a sputtering gas such as Ar or the like into the processing chamber 120 is provided in a wall surface of the processing chamber 120.

In the sputtering apparatuses 51 and 90, in a state that a magnetic field is generated between the targets 125, while the substrate G held on the holding table 122 is transferred along the direction orthogonal to the transfer route L, glow discharge occurs between the targets 125 and the ground electrodes 126, and, thus, plasma is generated between the targets 125. A sputtering is performed by this plasma, so that a material of the targets 125 may adhere to the upper surface of the substrate G and, thus, the cathode layer 13 or the conductive layer 15 may be formed consecutively by a sputtering method.

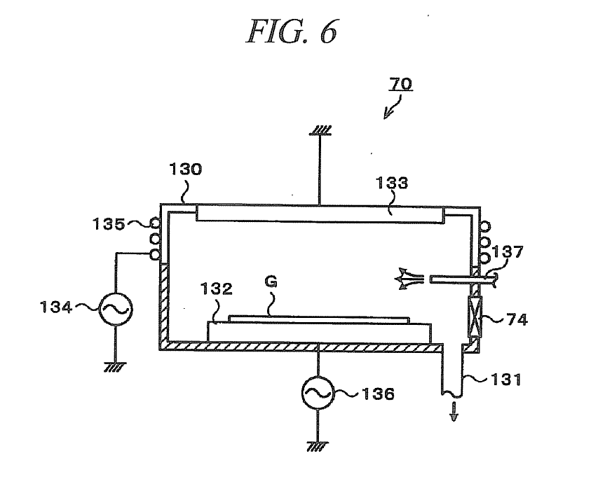

FIG. 6 is a schematic diagram for explaining the etching apparatus 70. The etching apparatus 70 depicted in FIG. 6 forms a pattern on the light emitting layer 11 and the work function adjustment layer 12 depicted in FIG. 1E by a plasma etching method.

The etching apparatus 70 has a sealed processing chamber 130. A front surface of the processing chamber 130 of the etching apparatus 70 is connected with a side surface of the third transfer module 25 via the gate valve 74.

A bottom surface of the processing chamber 130 is connected with an exhaust line 131 including a vacuum pump (not shown), so that the inside of the processing chamber 130 is depressurized. Within the processing chamber 130, a holding table 132 configured to horizontally hold the substrate G is installed. The substrate G is mounted on the holding table 132 in a face-up state in which the substrate G's upper surface on which the light emitting layer 11 is formed faces upwards.

An earth electrode 133 is installed on a ceiling of the processing chamber 130 so as to face an upper surface of the holding table 132. Further, coils 135 receiving high frequency power from a high frequency power supply 134 are provided outside the processing chamber 130. The holding table 132 is configured to receive high frequency power from a high frequency power supply 136. A gas supply unit 137 supplies an etching gas such as N₂/Ar or the like into the processing chamber 130. In the etching apparatus 70, the etching gas supplied into the processing chamber 130 is excited into plasma by high frequency power applied to the coils 135, so that the light emitting layer 11 and the work function adjustment layer 12 are etched by the plasma to have a predetermined pattern.

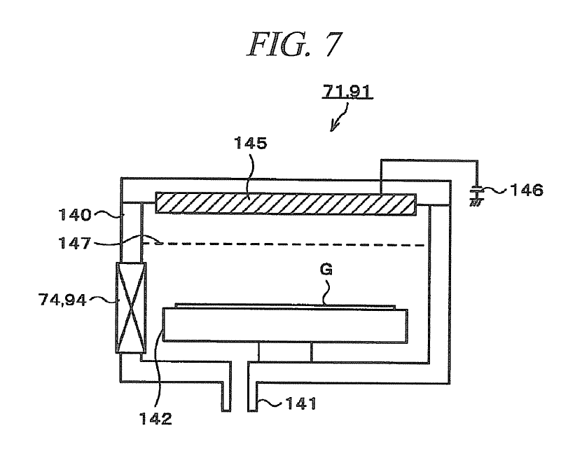

FIG. 7 is a schematic diagram for explaining the CVD apparatuses 71 and 91. The CVD apparatuses 71 and 91 have the same configuration. The CVD apparatuses 71 and 91 depicted in FIG. 7 form the protective layer 14 depicted in FIG. 1F and the protective layer 16 depicted in FIG. 1H by a CVD method.

Each of the CVD apparatuses 71 and 91 includes a sealed processing chamber 140. A front surface of the processing chamber 140 of the CVD apparatus 71 is connected with a side surface of the third transfer module 25 via the gate valve 74 and a front surface of the processing chamber 140 of the CVD apparatus 91 is connected with a side surface of the fourth transfer module 27 via the gate valve 94.

A bottom surface of the processing chamber 140 is connected with an exhaust line 141 including a vacuum pump (not shown), so that the inside of the processing chamber 140 is depressurized. Within the processing chamber 140, a holding table 142 configured to horizontally hold the substrate G is installed. The substrate G is mounted on the holding table 142 in a face-up state in which the substrate G's upper surface on which the light emitting layer 11 is formed faces upwards.

An antenna 145 is installed on a ceiling of the processing chamber 120 and a microwave is applied from a power source 146 to the antenna 145. Further, a gas supply unit 147 for supplying a film forming source gas into the processing chamber 140 is installed between the antenna 145 and the holding table 142. The gas supply unit 147 is formed in, for example, a grid pattern, so that the microwave may pass therethrough. In these CVD apparatuses 71 and 91, the film forming source gas supplied from the gas supply unit 147 may be excited into plasma by the microwave supplied from the antenna 145 above the upper surface of the substrate G held on the holding table 142, so that the insulating protective layers 14 and 16 made of, for example, silicon nitride (SiN) may be formed.

Hereinafter, there will be explained a process of manufacturing the organic EL device A by the substrate processing system 1 configured as described above. Above all, the substrate G loaded into the substrate processing system 1 via the loader 20 is loaded into the cleaning apparatus 35 by the transfer arm 37 of the first transfer module 21. In this case, the anode layer 10 made of, for example, ITO is formed in advance in a predetermined pattern on the surface of the substrate G. The substrate G is loaded into the cleaning apparatus 35 while the substrate G is in a state (face-up state) in which the surface on which the anode layer 10 is formed faces upwards. A cleaning process is performed onto the substrate G in the cleaning apparatus 35 and the cleaned substrate G is loaded from the cleaning apparatus 35 to the vapor deposition apparatus 22 by the transfer arm 37 of the first transfer module 21.

In the vapor deposition apparatus 22, the substrate G is held onto the holding table 102 in a state (face-up state) that the surface (film-formed surface) of the substrate faces upwards and transferred along the transfer route L within the depressurized processing chamber 100. Meanwhile, within the processing chamber 100, vapor of film forming materials is discharged from each of the vapor deposition heads 105. Consequently, as depicted in FIG. 1B, the light emitting layer 11 is formed on the upper surface of the substrate G by forming a hole transport layer, a non-light-emitting layer, a blue light emitting layer, a red light emitting layer, a green light emitting layer, and an electron transport layer in sequence on the upper surface of the substrate G.

The substrate G having thereon the light emitting layer 1 in the vapor deposition apparatus 22 is unloaded from the vapor deposition apparatus 22 by the transfer arm 43 positioned in the front loading/unloading area 40 of the second transfer module 23 and the substrate G is loaded into the vapor deposition apparatus 50.

In the vapor deposition apparatus 50, the substrate G is held onto the holding table 112 in a state (face-up state) that the surface (film-formed surface) of the substrate faces upwards and transferred along the direction orthogonal to the transfer route L within the depressurized processing chamber 110. Meanwhile, within the processing chamber 110, vapor of a film forming material such as Li is discharged from the vapor deposition head 115. Consequently, as depicted in FIG. 1C, the work function adjustment layer 12 is formed on the light emitting layer 11 on the upper surface of the substrate G.

The substrate G having thereon the work function adjustment layer 12 in the vapor deposition apparatus 50 is unloaded from the vapor deposition apparatus 50 by the transfer arm 43 positioned in the front loading/unloading area 40 of the second transfer module 23 and the substrate G is transferred to the transit table 45 installed in the stocking area 42 within the second transfer module 23.

The substrate G transferred to the transit table 45 is taken out of the transit table 45 by the transfer arm 44 installed in the rear loading/unloading area 41 within the second transfer module 23 and the substrate G is loaded into the mask aligner 53.

In the mask aligner 53, the mask M is aligned and placed on the upper surface of the substrate G. By way of example, the mask M is unloaded from the mask stocking chamber 52 by the transfer arm 43 installed in the front loading/unloading area 40 and transferred to the transit table 45 installed in the stocking area 42 within the second transfer module 23, and the mask M is taken out of the transit table 45 by the transfer arm 44 installed in the rear loading/unloading area 41 and the mask M is loaded into the mask aligner 53.

The substrate G on which the mask M is aligned is taken out of the mask aligner 53 by the transfer arm 44 installed in the rear loading/unloading area 41 within the second transfer module 23 and the substrate G is loaded into the sputtering apparatus 51.

In the sputtering apparatus 51, the substrate G is held onto the holding table 122 in a state (face-up state) that the surface (film-formed surface) of the substrate faces upwards and transferred along the direction orthogonal to the transfer route L within the depressurized processing chamber 120. Meanwhile, within the processing chamber 120, voltage is applied between the targets 125 and the ground electrodes 126 and a sputtering gas is supplied from the gas supply unit 129. Consequently, as depicted in FIG. 1D, the cathode layer 13 on the work function adjustment layer 12 is formed on the upper surface of the substrate G in a predetermined pattern by a sputtering method using the mask M.

Further, in the sputtering apparatus 51, the substrate G having thereon the cathode layer 13 is unloaded from the sputtering apparatus 51 by the transfer arm 44 installed in the rear loading/unloading area 41 within the second transfer module 23 and the substrate G is loaded into the first transit chamber 24.

Then, the substrate G is unloaded from the first transit chamber 24 by the transfer arm 63 positioned in the front loading/unloading area 60 of the third transfer module 25 and the substrate G is loaded into the etching apparatus 70.

In the etching apparatus 70, the substrate G is held onto the holding table 132 in a state (face-up state) that the surface (film-formed surface) of the substrate faces upwards within the depressurized processing chamber 130 while the substrate G is. Meanwhile, high frequency power is applied to the holding table 132 from the high frequency power supply 136 and an etching gas such as N₂/Ar is supplied from the gas supply unit 137 into the processing chamber 130. Consequently, as depicted in FIG. 1E, the light emitting layer 11 and the work function adjustment layer 12 on the upper surface of the substrate G are etched by plasma while using the cathode layer 13 as a mask, so that the light emitting layer 11 and the work function adjustment layer 12 are patterned.

The substrate G having thereon the patterned light emitting layer 11 and the patterned work function adjustment layer 12 is unloaded from the etching apparatus 70 by the transfer arm 63 positioned in the front loading/unloading area 60 of the third transfer module 25 and the substrate G is transferred to the transit table 65 installed in the stocking area 62 within the third transfer module 25.

Then, the substrate G transferred to the transit table 65 is taken out of the transit table 65 by the transfer arm 64 installed in the rear loading/unloading area 61 within the third transfer module 25 and the substrate G is loaded into the mask aligner 73.

In the mask aligner 73, the mask M is aligned and placed on the upper surface of the substrate G. By way of example, the mask M is unloaded from the mask stocking chamber 72 by the transfer arm 63 installed in the front loading/unloading area 60 and transferred to the transit table 65 installed in the stocking area 62 within the third transfer module 25, and the mask M is taken out of the transit table 65 by the transfer arm 64 installed in the rear loading/unloading area 61 and the mask M is loaded into the mask aligner 73.

The substrate G on which the mask M is aligned is taken out of the mask aligner 73 by the transfer arm 64 installed in the rear loading/unloading area 61 within the third transfer module 25 and the substrate G is loaded into the CVD apparatus 71.

In the CVD apparatus 71, the substrate G is held onto the holding table 142 in a state (face-up state) that the surface (film-formed surface) of the substrate faces upwards within the depressurized processing chamber 140. Meanwhile, within the processing chamber 140, microwave is applied from the power supply 146 to the antenna 145 and a film forming source gas is supplied from the gas supply unit 147. Consequently, as depicted in FIG. 1F, the insulating protective layer 14 is patterned and formed on the upper surface of the substrate G so as to cover edges of the light emitting layer 11, the work function adjustment layer 12, and the cathode layer 13 and a part of the anode layer 10.

The substrate G having thereon is unloaded from the CVD apparatus 71 by the transfer arm 64 installed in the rear loading/unloading area 61 of the third transfer module 25 and the substrate G is loaded into the second transit chamber 26.

Then, the substrate G is unloaded from the second transit chamber 26 by the transfer arm 83 positioned in the front loading/unloading area 80 of the fourth transfer module 27 and the substrate G is loaded into the mask aligner 92.

In the mask aligner 92, the mask M is aligned and placed on the upper surface of the substrate G. The substrate G having thereon the aligned mask M is taken out of the mask aligner 92 by the transfer arm 83 positioned in the front loading/unloading area 80 of the fourth transfer module 27 and the substrate G is loaded into the sputtering apparatus 90.

In the sputtering apparatus 90, the substrate G is held onto the holding table 122 in a state (face-up state) that the surface (film-formed surface) of the substrate faces upwards and transferred along the direction orthogonal to the transfer route L within the depressurized processing chamber 120. Meanwhile, within the processing chamber 120, voltage is applied between the targets 125 and the ground electrodes 126 and a sputtering gas is supplied from the gas supply unit 129. Consequently, as depicted in FIG. 1G, the conductive layer 15 is formed on the upper surface of the substrate G in a predetermined pattern by a sputtering method using the mask M.

Then, the substrate G having thereon the conductive layer 15 is unloaded from the sputtering apparatus 90 by the transfer arm 83 positioned in the front loading/unloading area 80 of the fourth transfer module 27 and the substrate G is transferred to the transit table 85 installed in the stocking area 82 within the fourth transfer module 27. Further, the transit table 85 serves as a mask stocking chamber within the fourth transfer module 27.

Thereafter, the substrate G transferred to the transit table 85 is taken out of the transit table 85 by the transfer arm 84 installed in the rear loading/unloading area 81 within the fourth transfer module 27 and the substrate G is loaded into the mask aligner 93.

In the mask aligner 93, the mask M is aligned and placed on the upper surface of the substrate G. The substrate G having thereon the aligned mask M is taken out of the mask aligner 93 by the transfer arm 84 positioned in the rear loading/unloading area 81 of the fourth transfer module 27 and the substrate G is loaded into the CVD apparatus 91.

In the CVD apparatus 91, the substrate G is held onto the holding table 142 in a state (face-up state) that the surface (film-formed surface) of the substrate faces upwards within the depressurized processing chamber 140. Meanwhile, microwave is applied to the antenna 145 from the power supply 146 within the processing chamber 140 and a film forming source gas is supplied from the gas supply unit 147. Consequently, as depicted in FIG. 1H, the insulating protective layer 16 is patterned and formed on the upper surface of the substrate G so as to cover a part of the conductive layer 15.

Then, the substrate G having thereon the protective layer 16 is unloaded from the CVD apparatus 91 by the transfer arm 84 installed in the rear loading/unloading area 81 of the fourth transfer module 27 and the substrate G is transferred into the unloader 28. The organic EL device manufactured as described above is unloaded by the unloader 28 to the outside of the substrate processing system 1.

In the substrate processing system 1, since moisture in the atmosphere is undesirable for an organic EL device, the organic EL device can be manufactured in a vacuum state by consecutively performing various film forming processes or etching processes. In this substrate processing system 1, two loading/unloading areas (the front loading/unloading area 40 and the rear loading/unloading area 41) and the stocking area 42 positioned between the front loading/unloading area 40 and the rear loading/unloading area 41 are formed in the second transfer module 23. In the side surface of the second transfer module 23, the vapor deposition apparatus 50 and the mask stocking chamber 52 are connected at positions facing the front loading/unloading area 40 and the sputtering apparatus 51 and the mask aligner are connected at positions facing the rear loading/unloading area 41. For this reason, a gap corresponding to the stocking area 42 is formed between the vapor deposition apparatus 50 and the sputtering apparatus 51 on the lateral side of the second transfer module 23. Likewise, a gap corresponding to the stocking area 42 is formed between the mask stocking chamber 52 and the mask aligner 53. By using these gaps, for example, a cleaning process and a repairing process for the vapor deposition apparatus 50 and the sputtering apparatus 51 can be performed, and also, a loading/unloading process of the mask M, a cleaning process and a repairing process for the mask stocking chamber 52 and the mask aligner 53 can be performed.

Likewise, two loading/unloading areas (the front loading/unloading area 60 and the rear loading/unloading area 61) and the stocking area 62 positioned between the front loading/unloading area 60 and the rear loading/unloading area 61 are formed in the third transfer module 25. In the side surface of the third transfer module 25, the etching apparatus 70 and the mask stocking chamber are connected at positions facing the front loading/unloading area 60 and the CVD apparatus 71 and the mask aligner 73 are connected at positions facing the rear loading/unloading area 61. For this reason, a gap corresponding to the stocking area 62 is formed between the etching apparatus 70 and the CVD apparatus 71 on the lateral side of the third transfer module 25. Likewise, a gap corresponding to the stocking area 62 is formed between the mask stocking chamber 72 and the mask aligner 73. By using these gaps, for example, a cleaning process and a repairing process for the etching apparatus 70 and the CVD apparatus 71 can be performed, and also, a loading/unloading process of the mask M, a cleaning process and a repairing process for the mask stocking chamber 72 and the mask aligner 73 can be performed.

In the same manner as stated above, two loading/unloading areas (the front loading/unloading area 80 and the rear loading/unloading area 81) and the stocking area 82 positioned between the front loading/unloading area 80 and the rear loading/unloading area 81 are formed in the fourth transfer module 27. In the side surface of the fourth transfer module 27, the sputtering apparatus 80 and the mask aligner 92 are connected at positions facing the front loading/unloading area 80 and the CVD apparatus 91 and the mask aligner 93 are connected at positions facing the rear loading/unloading area 81. For this reason, a gap corresponding to the stocking area 82 is formed between the sputtering apparatus 90 and the CVD apparatus 91 on the lateral side of the fourth transfer module 27. Likewise, a gap corresponding to the stocking area 82 is formed between the mask aligner 92 and the mask aligner 93. By using these gaps, for example, a cleaning process and a repairing process for the sputtering apparatus 90 and the CVD apparatus 91 can be performed, and also, a loading/unloading process of the mask M, a cleaning process and a repairing process for the mask aligner 92 and the mask aligner 93 can be performed.

Since the gaps between various processing apparatuses connected with the side surfaces of the transfer modules 23, 25 and 27 can be increased, this substrate processing system 1 has high maintainability.

There has been explained the embodiment of the present invention, but the present invention is not limited thereto. It is clear to those skilled in the art that various changes and modifications may be made without changing technical conception and essential features of the present invention, and it shall be understood that all modifications and embodiments conceived from the meaning and scope of the claims and their equivalents are included in the scope of the present invention.

By way of example, in the substrate processing system 1 for manufacturing the organic EL device A described in the above embodiment, a sealing film such as a nitride film is formed on the surface of the substrate as well as on the mask M used in the sputtering process. If a deposit formed on the mask M remains on the mask M, it may be a contaminant and may have a bad influence on a film forming process. For this reason, the mask M needs to be cleaned to remove the deposit at a proper time.

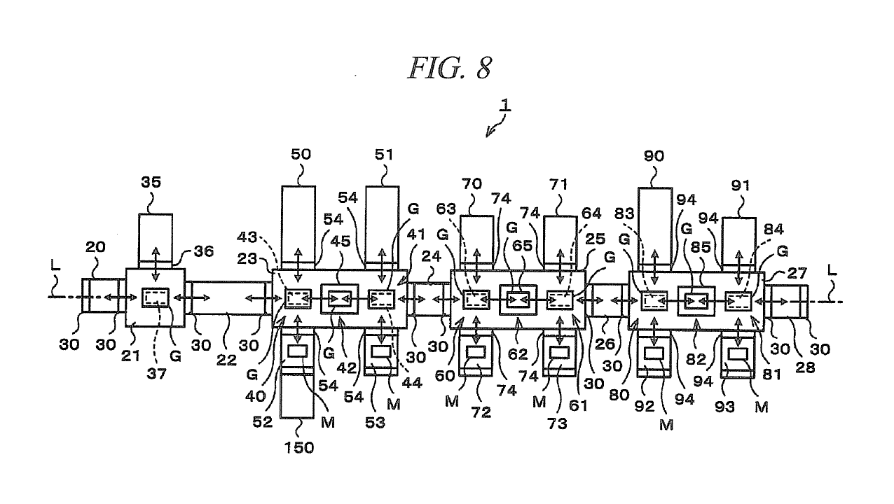

Accordingly, in a substrate processing system 1 illustrated in FIG. 8, in addition to a mask stocking chamber 52 connected to a side surface of a second transfer module 23, a mask cleaning apparatus 150 is further connected thereto via a gate valve 151.

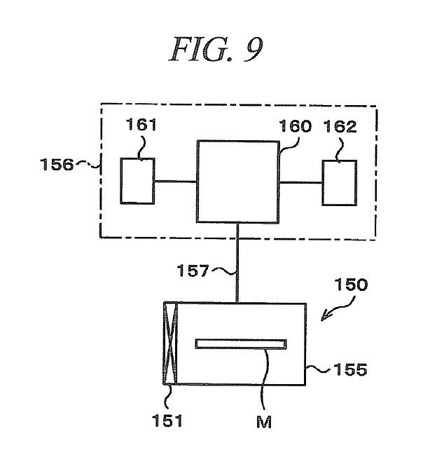

As depicted in FIG. 9, a mask cleaning apparatus 150 includes a sealed processing chamber 155 and a mask M is loaded into the processing chamber 155 from the mask stocking chamber 52 via the gate valve 151. Further, the processing chamber 155 is connected with a cleaning gas supply line 157 for supplying a cleaning gas activated in a cleaning gas generation unit 156. The cleaning gas generation unit 156 is separately provided outside the processing chamber 155 and adopts a remote plasma method in which the cleaning gas activated by plasma in the cleaning gas generation unit 156 is introduced into the processing chamber 155.

As depicted in FIG. 9, the cleaning gas generation unit 156 includes an activation chamber 160, a cleaning gas supply source 161 for supplying the cleaning gas into the activation chamber 160, and an inert gas supply source 162 for supplying an inert gas into the activation chamber 160.

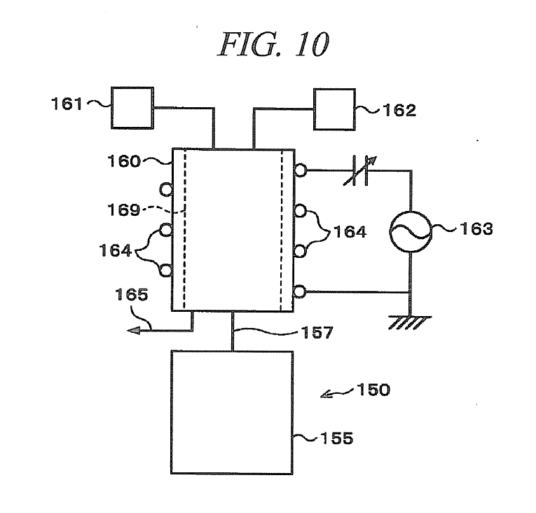

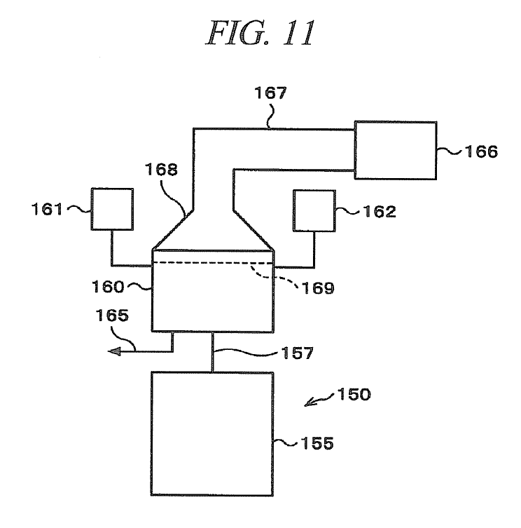

Hereinafter, examples of the activation chamber 160 are explained with reference to FIGS. 10 and 11. Outside an activation chamber 160 illustrated in FIG. 10, coils 164 receiving high frequency power from a high frequency power supply 163 are installed. Further, the activation chamber 160 is connected with an exhaust line 165 including a vacuum pump (not shown), so that the inside of the activation chamber 160 is depressurized. The activation chamber 160 illustrated in FIG. 10 is supplied with the cleaning gas and the inert gas from the cleaning gas supply source 161 and the inert gas supply source 162, respectively, and high frequency power applied from the high frequency power supply 136 passes through a dielectric member 169, so that high density plasma is generated by an inductively coupled plasma (ICP) method. In the activation chamber 160 illustrated in FIG. 10, the cleaning gas can be activated by using a downflow plasma method, so that activated radicals can be introduced into the mask cleaning apparatus 150 under an approximately normal temperature. Therefore, a mask can be cleaned without thermal damage.

In an activation chamber 160 illustrated in FIG. 11, a microwave generated by a microwave generator 166 is introduced into the activation chamber 160 via a waveguide 167 and a dielectric member 169 installed in a horn antenna 168. The activation chamber 160 is connected with an exhaust line 165 including a vacuum pump (not shown), so that the inside of the activation chamber 160 is depressurized. The activation chamber 160 illustrated in FIG. 11 is configured to generate high density plasma by exciting a cleaning gas supplied from a cleaning gas supply source 161 and an inert gas supplied from the inert gas supply source 162 by microwave power within the activation chamber 160. In the activation chamber 160 illustrated in FIG. 11, the cleaning gas can be activated by using a downflow plasma method, so that activated radicals can be introduced into the mask cleaning apparatus 150 under an approximately normal temperature. Therefore, a mask can be cleaned without thermal damage. Alternatively, a slot antenna may be used instead of the horn antenna 168.

The cleaning gas supply source 161 supplies a cleaning gas including any one of an oxygen gas, a fluorine gas, a chlorine gas, an oxygen gas compound, a fluorine gas compound, a chlorine gas compound (for example, O₂, Cl, NF₃, diluted F₂, CF₄, C₂F₆, C₃F₈, SF₆ and ClF₃) to the activation chamber 160. The inert gas supply source 162 supplies an inert gas such as Ar or He to the activation chamber 160. In the activation chamber 160, the supplied cleaning gas and inert gas are activated by ICP or plasma generated by microwave power, so that oxygen radicals, fluorine radicals, chlorine radicals and the like can be generated. The cleaning gas activated in the activation chamber 160 of the cleaning gas generation unit 156 is supplied into the processing chamber 155 via the cleaning gas supply line 157. In this way, the cleaning gas generation unit 156 adopts a so-called remote plasma method in which the cleaning gas activated in the activation chamber 160 is supplied into the processing chamber 155 via the cleaning gas supply line 157 while the cleaning gas generation unit 156 is spaced apart from the processing chamber 155.

By way of example, in the substrate processing system 1 illustrated in FIG. 8, a mask M used for a sputtering process in the sputtering apparatus 51 is cleaned at any time by using a high etching property cleaning gas including oxygen radicals activated within the processing chamber 155 of the mask cleaning apparatus 150, and, thus, a film forming process can be performed in good condition. In this way, by performing a so-called in-situ cleaning, a down-time of the processing system 1 can be reduced, and, thus manufacturing efficiency can be improved.

There has been explained a case in which the mask stocking chamber 52 connected with the side surface of the second transfer module 23 is connected with the mask cleaning apparatus 150 as a representative example, but the same mask cleaning apparatus 150 may be connected with the sputtering apparatus 51, the mask aligner 53, the CVD apparatus 71, the mask stocking chamber 72, the mask aligner 73, the sputtering apparatus 90, the CVD apparatus 91, the mask aligner 92, the mask aligner 93 or the like. Alternatively, the same mask cleaning apparatus 150 may be connected with the side surface of the second transfer module 23, third transfer module 25 or fourth transfer module 27.

When the mask M is cleaned in the mask cleaning apparatus 150, O₂/Ar of about 2000 sccm to about 10000 sccm/about 4000 sccm to about 10000 sccm (for example, O₂/Ar of about 2000 sccm/about 6000 sccm) is supplied into the processing chamber 155, for example, into the cleaning gas generation unit 161 and an internal pressure of the processing chamber 155 is adjusted to be in the range of about 2.5 Torr to about 8 Torr. Further, a small amount of N₂ may be added as an addition gas.

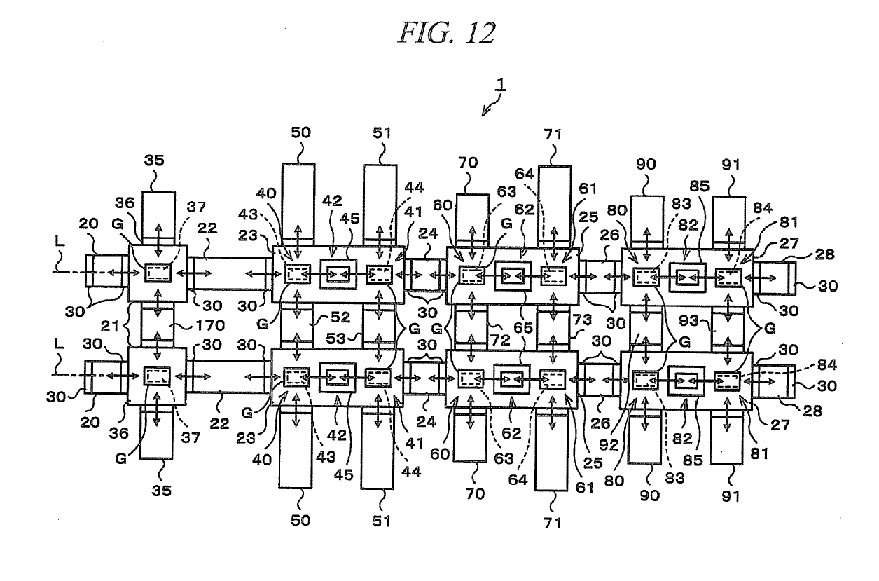

FIG. 2 shows an example in which the straight transfer route L is formed in a single row by arranging the loader 20, the first transfer module 21, the vapor deposition apparatus 22 for the light emitting layer 11, the second transfer module 23, the first transit chamber 24, the third transfer module 25, the second transit chamber 26, the fourth transfer module 27 and the unloader 28. However, as shown in a processing system 1 of FIG. 12, straight transfer routes L may be formed in two rows. In the processing system 1 illustrated in FIG. 12, between the two transfer routes L, a new mask stocking chamber 170 is installed between first transfer modules 21 but a mask stocking chamber 52 and a mask aligner 53 are shared between second transfer modules 23, a mask stocking chamber 72 and a mask aligner 73 are shared between third transfer modules 25, and mask aligners 92 and 93 are shared between fourth transfer modules 27. In this way, transfer routes L may be formed in plural rows.

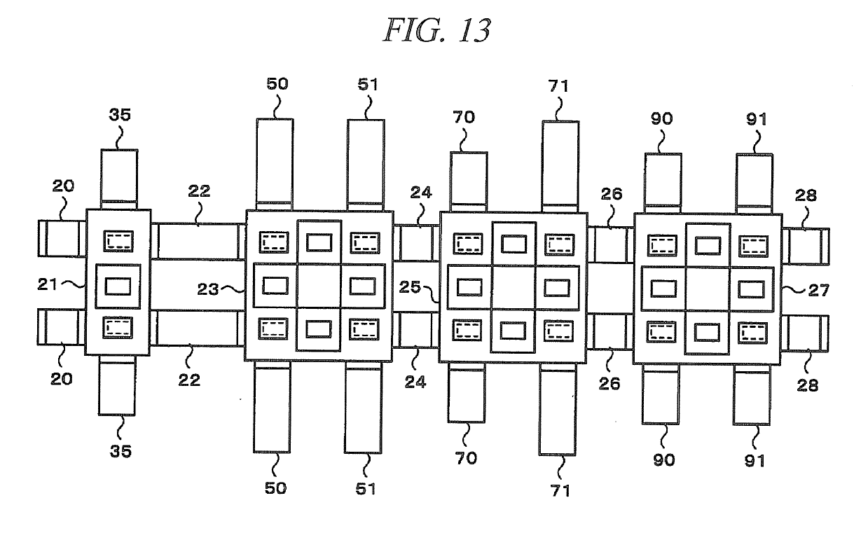

If transfer routes L are formed in plural rows, as depicted in FIG. 13, a substrate G may be transferred between the transfer routes L in a first transfer module 21, a second transfer module 23, a third transfer module 25, and a fourth transfer module 27.

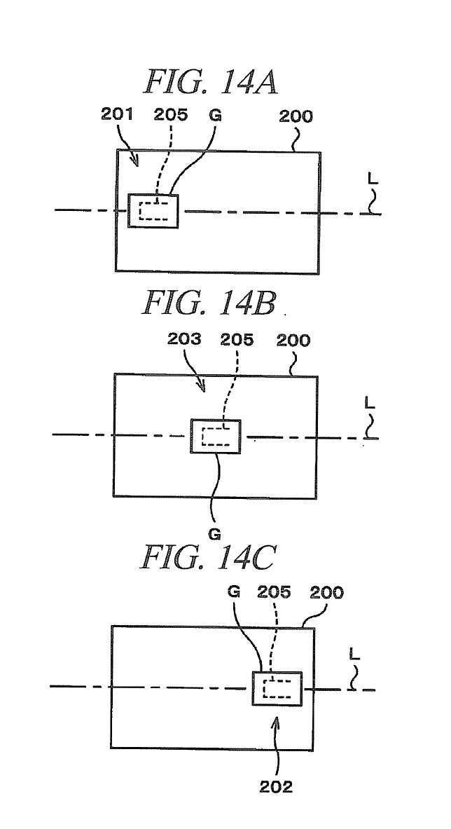

Further, a transfer arm movable along a transfer route L may be installed within a transfer module. FIGS. 14A to 14C show an example in which a front loading/unloading area 201, a rear loading/unloading area 202, and a stocking area 203 between the front loading/unloading area 201 and the rear loading/unloading area 202 are formed within a transfer module 200. A transfer arm 205 can move in the front loading/unloading area 201, the stocking area 203, and the rear loading/unloading area 202. According to the example illustrated in FIGS. 14A to 14C, as depicted in FIG. 14A, the transfer arm 205 moves to the front loading/unloading area 201 and the transfer arm 205 loads and unloads a substrate G with respect to each processing apparatus connected with side surfaces of the transfer module 200. Further, as depicted in FIG. 14B, the transfer arm 205 moves to the stocking area 203 and the transfer arm 205 holds the substrate G between the front loading/unloading area 201 and the rear loading/unloading area 202. Furthermore, as depicted in FIG. 14C, the transfer arm 205 moves to the rear loading/unloading area 202 and the transfer arm 205 loads and unloads the substrate G with respect to each processing apparatus connected with side surfaces of the transfer module 200.

In the transfer module 200 illustrated in FIGS. 14A to 14C, a gap corresponding to the stocking area 203 is formed between the processing apparatuses at each side surface of the transfer module 200. By using the gaps, for example, a cleaning process and a repairing process of each processing apparatus can be performed, and also, a loading/unloading process of a mask M, a cleaning process and a repairing process can be performed, so that maintainability can be improved. In the transfer module 200 illustrated in FIGS. 14A to 14C, a number of the transfer arms 205 can be reduced, so that a low-cost apparatus can be provided.

FIG. 2 shows an example in which each of the second transfer module 23, the third transfer module 25 and the fourth transfer module 27 includes the front loading/unloading area 40, 60 or 80, the rear loading/unloading area 41, 61 or 81 and the stocking area 42, 62 or 82 arranged in series as one unit, but a configuration of the transfer module of the present invention is not limited to the example shown in FIG. 2. By way of example, the transfer module may include a multiple number of loading/unloading areas and one or more stocking areas connected with each other via gate valves. A pressure within each of the loading/unloading areas and each of the stocking areas in the transfer module may be controlled independently.

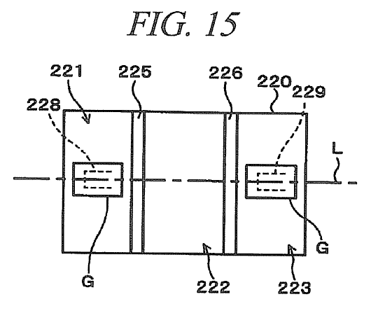

FIG. 15 shows another example in which a transfer module 220 includes a front loading/unloading area 221, a stocking area 222, and a rear loading/unloading area 223 which are arranged in sequence along a transfer route L and each gate valve 225 and 226 is installed between each of the loading/unloading areas 221 and 223 and the stocking area 222. Here, a pressure within each of the loading/unloading areas 221 and 223 and the stocking area 222 can be controlled independently. Further, although a multiple number of transfer modules are arranged in a substrate processing system, one of them is explained as an example.

As depicted in FIG. 15, the front loading/unloading area 221 and the stocking area 222 are connected with each other via the gate valve 225 and the stocking area 222 and the rear loading/unloading area 223 are connected with each other via the gate valve 226. Further, a transfer arm 228 is installed within the front loading/unloading area and a transfer arm 229 is installed within the rear loading/unloading area. A substrate G may be transferred between the front loading/unloading area 221 and the stocking area 222 via the gate valve 225 and between the stocking area 222 and the rear loading/unloading area 223 via the gate valve 226. Various processing apparatuses, which are not illustrated, such as a vapor deposition apparatus are connected with side surfaces of the front loading/unloading area 221 and rear loading/unloading area 223 via gate valves and the substrate G may be transferred between the transfer module 220 and each of the processing apparatuses by the transfer arms 228 and 229.

In the same manner as the above-described embodiment, a gap corresponding to the stocking area 222 is formed between the processing apparatuses at each side surface of the transfer module 220 illustrated in FIG. 15. By using the gaps, for example, a cleaning process and a repairing process for each processing apparatus can be performed, and also, a loading/unloading process of a mask M, a cleaning process and a repairing process can be performed, so that maintainability can be improved.

Since the gate valves 225 and 226 are installed between each of the loading/unloading areas 221 and 223 and the stocking area 222, the pressure within each of the loading/unloading areas 221 and 223 and the stocking area 222 can be controlled independently. For this reason, when the substrate G is loaded and unloaded between each of the loading/unloading areas 221 and 223 and each of the non-illustrated processing apparatuses connected with side surfaces thereof, a pressure control (control of an internal pressure between apparatuses from/to which the substrate moves) is carried out efficiently and throughput of the substrate processing system can be improved. This is because, in FIG. 2, a volume of which a pressure needs to be controlled during a transfer of a substrate is the entire transfer module, whereas, in FIG. 15, a pressure control can be carried out with respect to a volume of each loading/unloading area since an internal pressure of each loading/unloading area can be controlled independently with a gate valve, and, thus, a time for the pressure control is greatly reduced. In particular, in case of manufacturing a recently demanded large-sized panel (for example, size G6: 1500 mm×1800 mm or more) for a TV or the like, a volume of a transfer module in which a transfer and a pressure control are carried out is great, and, thus, it takes a very long time to control a pressure of the transfer module, resulting in a decrease in productivity or throughput. However, as described above, since a pressure control is carried out with respect to a volume of each loading/unloading area, it is possible to prevent a decrease in productivity or throughput even when a large-sized substrate is processed and it is possible to perform a process onto the substrate under a proper condition.

Further, internal pressures of the front loading/unloading area 221 and the rear loading/unloading area 223 may vary depending on a kind of a processing apparatus connected with a side surface of each of the loading/unloading areas. If the substrate G is transferred between the front loading/unloading area 221 and the rear loading/unloading area 223 having different internal pressures, a pressure control is carried out only in the stocking area 222 and, thus, a change in the internal pressure of each loading/unloading area can be minimized. Therefore, a time for the pressure control can be reduced and a time during which a substrate transfer or a film forming process cannot be performed can be shortened, and, thus, throughput of the entire system can be improved. In particular, in case of using a processing apparatus under an atmospheric pressure, an efficient control of a pressure between an atmospheric pressure and an approximate vacuum pressure is very useful. That is, a problem is that a time for a pressure control for each transfer module is greatly non-uniform, but it can be solved and a decrease in productivity can be prevented.

The present invention has been explained for the example of manufacturing the organic EL device A but the present invention can also be applied to a substrate processing system for various electronic devices. The substrate G as a target object to be processed may be various substrates such as a glass substrate, a silicon substrate, and a square-shaped or ring-shaped substrate. Further, the substrate G may be a target object other than a substrate. Furthermore, a number or arrangement of each processing apparatus may be arbitrarily changed.

### INDUSTRIAL APPLICABILITY

The present invention can be applied to a substrate processing system for manufacturing, for example, an organic EL device.

1. A substrate processing system for processing a substrate, comprising:
at least one transfer module configured to be evacuable and arranged along a straight transfer route,
wherein the transfer module includes a plurality of loading/unloading areas, each of which is configured to load/unload the substrate with respect to a processing apparatus, and at least one stocking area positioned between the loading/unloading areas, and
the processing apparatus is connected with a side surface of the loading/unloading area.

2. The substrate processing system of claim 1, wherein the transfer module has a hexahedral structure of which a longitudinal direction is arranged along the transfer route.

3. The substrate processing system of claim 1, wherein, in the transfer module, the plurality of loading/unloading areas is connected with the at least one stocking area via gate valves.

4. The substrate processing system of claim 1, wherein a transfer arm is installed in each of the loading/unloading areas and a transit table of the substrate is installed in the stocking area within the transfer module.

5. The substrate processing system of claim 1, wherein a transfer arm configured to be movable between each of the loading/unloading areas and the stocking area is installed within the transfer module.

6. The substrate processing system of claim 1, wherein the at least one transfer module is plural in number, and
an evacuable transit chamber is installed between the transfer modules.

7. The substrate processing system of claim 1, wherein a film forming process is performed on an upper surface of the substrate in a face-up state.

8. The substrate processing system of claim 1, wherein a mask aligner configured to place a mask having a predetermined pattern on the substrate is connected with a side surface of the transfer module.

9. The substrate processing system of claim 1, further comprising:
a mask cleaning apparatus configured to clean a mask used for processing the substrate.

10. The substrate processing system of claim 9, wherein the mask cleaning apparatus includes a cleaning gas generation unit configured to activate a cleaning gas by plasma.

11. The substrate processing system of claim 9, wherein the mask cleaning apparatus includes a processing chamber configured to accommodate the mask and a cleaning gas generation unit spaced apart from the processing chamber, and
a cleaning gas activated by plasma in the cleaning gas generation unit is introduced into the processing chamber by using a remote plasma method.

12. The substrate processing system of claim 11, wherein the cleaning gas generation unit is configured to activate the cleaning gas by using a downflow plasma method.

13. The substrate processing system of claim 11, wherein the cleaning gas generation unit is configured to generate high density plasma by using an inductively coupled plasma method.

14. The substrate processing system of claim 11, wherein the cleaning gas generation unit is configured to generate high density plasma with microwave power.

15. The substrate processing system of claim 10, wherein the cleaning gas includes any one of an oxygen radical, a fluorine radical, and a chlorine radical.
